(19) United States
(12) Patent Application Publication
(10) Pub. No.: US 2013/0288425 A1
(43) Pub. Date: Oct. 31, 2013

(54) END POINT DETECTION FOR BACK CONTACT SOLAR CELL LASER VIA DRILLING

(71) Applicant: Solexel, Inc., (US)

(72) Inventors: Virendra V. Rana, Los Gatos, CA (US); Mehrdad M. Moslehi, Los Altos, CA (US); Pranav Anbalagan, Milpitas, CA (US); Heather Deshazer, Palo Alto, CA (US); Solene Coutant, San Jose, CA (US); Benjamin E. Rattle, Oakland, CA (US); Karl-Josef Kramer, San Jose, CA (US); Pawan Kapur, Burlingame, CA (US)

(73) Assignee: Solexel, Inc., Milpitas, CA (US)

(21) Appl. No.: 13/852,966

(22) Filed: Mar. 28, 2013

Related U.S. Application Data
(63) Continuation-in-part of application No. 13/204,626, filed on Aug. 5, 2011.
Application No. 13/204,626 is a continuation-in-part of application No. 13/271,212, filed on Oct. 11, 2011.
Application No. 13/271,212 is a continuation-in-part of application No. 13/807,631.
(60) Provisional application No. 61/617,033, filed on Mar. 28, 2012.
(60) Provisional application No. 61/725,434, filed on Nov. 12, 2012.

(51) Int. Cl. H01L 31/18

(52) U.S. Cl. CPC H01L 31/186
USPC 438/98

(57) ABSTRACT

Methods and structures for fabricating photovoltaic back contact solar cells having multi-level metallization using laser via drilling end point detection are provided.

### CROSS-REFERENCE TO RELATED APPLICATIONS

This application claims the benefit of U.S. Provisional Pat. App. Nos. 61/617,033 filed on Mar. 28, 2012 and 61/725,434 filed Nov. 12, 2012, which are hereby incorporated by reference in their entirety.

This application is a continuation-in-part of U.S. patent application Ser. Nos. 13/204,626 filed on Aug. 5, 2011, 13/271,212 filed Oct. 10, 2011, and 13/807,631 filed Dec. 28, 2012, which are hereby incorporated by reference in their entirety.

### FIELD OF THE INVENTION

The present disclosure relates in general to the fields of solar photovoltaic (PV) cells, and more particularly to back contact solar cells.

### BACKGROUND

Photovoltaic solar cells, including crystalline silicon solar cells, may be categorized as front-contact or back-contact cells based on the locations of the two polarities of the solar cell metal electrodes (emitter and base electrodes). Conventional front-contact cells have emitter electrode contacts on the cell frontside, also called the sunny side or light capturing side, and base electrode contacts on the cell backside. Back-contact cells, however, have both polarities of the metal electrodes with contacts on the cell backside. Major advantages of back-contact solar cells include:

(1) No optical shading and optical reflection losses from the metal contacts on the cell sunny side, due to the absence of metal electrode grids on the front side, which leads to an increased short-circuit current density (J_{sc}) for the back-contact solar cell;

(2) The electrode width and thickness may be increased and optimized without optical shading concerns since both metal electrodes are placed on the cell backside, therefore the series resistance of the emitter and base metal grids are reduced and the overall current carrying capability of metallization and the resulting cell conversion efficiency is increased;

(3) Back-contact solar cells are more aesthetically appealing than the front-contact cell due to the absence of the front metal grids.

However, significant fabrication challenges are presented for forming back side metallization patterns having both emitter and base contacts which are often exacerbated when processing sub-50-micron thick silicon substrates.

Further, to reduce the cost of solar cells there is a push to reduce the thickness of the crystalline silicon used and also at the same time increase the cell area for more power per cell and lower manufacturing cost per watt. Laser processing is suitable for these thin wafers and thin-film cell substrates as it is a completely non-contact, dry process and can be easily scaled to larger cell sizes. Laser processing is also attractive as it is generally a “green” and environmentally benign process, not requiring or using poisonous chemicals or gases. With suitable selection of the laser and the processing system, laser processing presents the possibility of very high productivity with a very low cost of ownership.

Despite these advantages, the use of laser processing in crystalline silicon solar cell fabrication has been limited because laser processes that provide high performance cells have not been developed. Solar cells often comprise varying and extremely sensitive layers of materials which makes laser processing difficult, particularly laser ablation and drilling.

### BRIEF SUMMARY OF THE INVENTION

Therefore, a need has arisen for improved back contact solar cell laser processing methods. In accordance with the disclosed subject matter, methods and structures for fabricating photovoltaic back contact solar cells having multi-level metallization using laser via drilling end point detection are disclosed which substantially eliminate or reduce the cost and fabrication disadvantages associated with previously developed back contact solar cell laser processing methods.

According to one aspect of the disclosed subject matter, a method is provided for fabricating photovoltaic back contact solar cells having multi-level metallization using laser via drilling end point detection. In one embodiment, a first metal layer of electrically conductive metal comprising base electrodes and emitter electrodes is formed on the backside of a semiconductor solar cell substrate such that the first metal layer base electrodes and emitter electrodes are connected to base regions and emitter regions on the semiconductor solar cell substrate. An electrically insulating backplane layer is attached on the semiconductor solar cell substrate comprising the first metal layer. Via holes are laser drilled through the backplane layer at specified positions to expose conductive metal on the first metal layer to form base contacts and emitter contacts. The via hole endpoints are detected during the laser via drilling process to extend the via hole through the electrically insulating backplane layer to the first metal layer and prevent breaching or punching through the first level metal. A second metal layer of electrically conductive metal is formed on the backplane layer. The second metal layer is contacted to the first metal layer through the via holes and provides conductive leads for electrical connections to the back-contact solar cell.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1A is a general process flow for the formation of a back-contact back-junction solar cell;

FIG. 1B is a representative manufacturing process flow for forming a back-contact/back-junction cell;

FIG. 2 is a process flow highlighting metallization process steps;

FIGS. 3A through 3D are cross-sectional diagrams showing the structure of the solar cell at each of the metallization steps described in FIG. 2;

FIGS. 4A through 4C are diagrams showing backside levels of the solar cell;

FIGS. 5A through 5C are SEM images showing vias drilled in single or double ply prepreg using a CO2 laser;

FIG. 6 is a micrograph image showing a top view of a via;

FIG. 7 is a schematic diagram showing a LIBS measurement scheme;

FIG. 8 is a schematic diagram showing a LIBS endpoint detection laser drilling scheme;

FIG. 9 is a schematic diagram showing a LIBS endpoint detection laser drilling scheme having an aligned LIBS signal collection and laser scan;

FIG. 9 is a schematic diagram showing a LIBS endpoint detection laser drilling scheme having an aligned LIBS signal collection and laser scan;

FIG. 10 is a schematic diagram showing a scheme using laser reflection for real-time endpoint detection;

FIG. 11 is a schematic diagram showing a scheme for end pointing using laser interferometry;

FIG. 12 is a schematic diagram showing a scheme for laser end point detection using a photoacoustic signal; and

FIG. 13 is a schematic diagram showing a scheme for laser end point detection using Raman spectroscopy.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

Importantly, the exemplary dimensions and calculations disclosed for embodiments are provided both as detailed descriptions for specific embodiments and to be used as general guidelines when forming and designing solar cells in accordance with the disclosed subject matter.

And although the present disclosure is described with reference to specific embodiments, such as back contact solar cells using monocrystalline silicon substrates having a thickness in the range of 10 to 200 microns and other described fabrication materials metallization layers, one skilled in the art could apply the principles discussed herein to front contact cells, other fabrication materials including alternative semiconductor materials (such as gallium arsenide, germanium, multi-crystalline silicon, etc.), metallization layers comprising metallization stacks, technical areas, and/or embodiments without undue experimentation.

The disclosed subject matter may be applied directly to the formation of high-efficiency back-contact, back-junction solar cells utilizing multi-layer backside metallization. As compared to front-contact solar cells, all back-junction, back-contact solar cells have all metallization (both base and emitter metallization and busbars) positioned on the backside of the cell and may eliminate sunlight shading due to metal runners on the front/sunnyside surface of the cell (optical shading losses of emitter metal fingers and busbars in the case of traditional front-contact solar cells). And while metallization (both the base and the emitter contacts) of the cells may be formed on the same side (opposite the sunnyside) to eliminate the optical shading losses, cell metallization complexity may be increased in some back contact designs as both the base and emitter electrodes have to be contacted on the same side. (However, in some instaces same side base and emitter contacts may simplify solar cell interconnections at the module level).

In some instances, an interdigitated metallization scheme requiring high metal pattern fidelity may be used. And as metallization pattern geometries may be formed increasingly smaller to increase cell efficiencies, the required thickness of the metallization layer may also significantly increase—for example 30 to 60 microns for a high conductivity metallization layer, such as copper or aluminum, on solar cells with dimensions of 125 mm×125 mm to 156 mm×156 mm.

Further, to reduce required metallization thickness, cell metallization may be partitioned into two metal layers/levels and a backplane material (such as a polymer sheet) may be formed between the two metallization layers to help reduce stress induced from the thicker higher-conductance second metallization level. In other words, the backplane material separates the two metallization layers and provides structural support to the solar cell substrate allowing for scaling to large area back-contact solar cells. Thus, each layer—first metallization layer, backplane material, and second metallization layer—may be optimized separately for cost and performance. And in some dual—level metallization embodiments, the two metal levels are patterned orthogonally with to each other, with the second (last) metal level having far fewer and coarser fingers than the first (on-cell) metal level.

And although the following exemplary back junction back contact solar cell designs and manufacturing processes described herein utilize two levels of metallization (dual layer metallization) which are separated by an electrically insulating and mechanically supportive backplane layer, the disclosed subject matter may be applicable in any fabrication embodiment requiring real-time in-situ process laser via drilling end-point detection including multi-level metallization patterns and metallization layers comprising metallization stacks (for example a first level metallization layer of Al/NiV/Sn). In some instances any combination of the backplane and metallization layers may serve as permanent structural support/reinforcement and provide embedded high-conductivity (aluminum and/or copper) interconnects for a high-efficiency thin crystalline silicon solar cell without significantly compromising solar cell power or adding to solar cell manufacturing cost. Laser processes using schemes for producing solar cells with high efficiency, and particularly thin-film crystalline silicon solar cells based sub-50-micron thick silicon substrates, are provided herein.

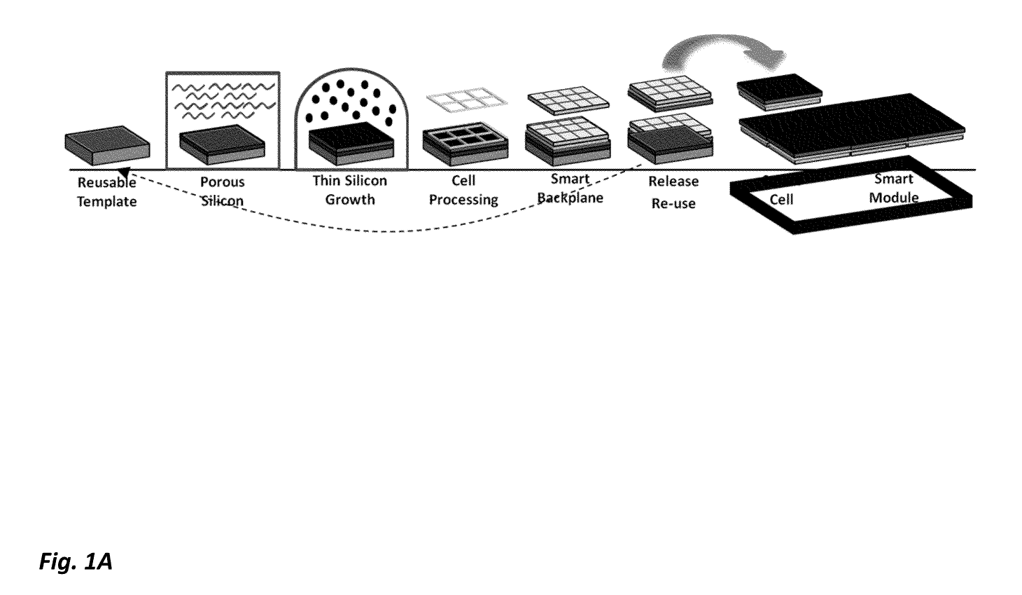

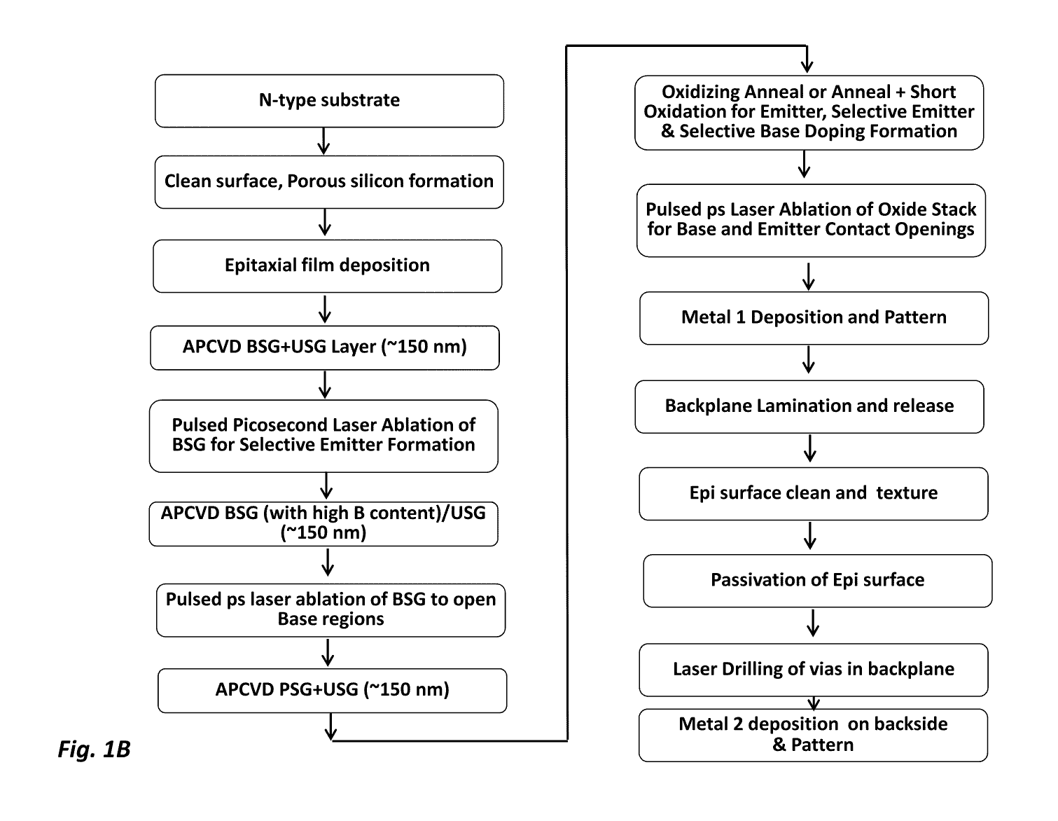

In some instances, the real-time in-situ process laser via drilling end-point detection systems and methods disclosed herein may be applied to and integrated with current back-contact back-junction solar cell structures and fabrication processes. FIG. 1A is a general process flow for the formation of a back-contact back-junction solar cell which may utilize real-time in-situ process laser via drilling end-point detection. Specifically, FIG. 1A is a general process flow highlighting key processing of a tested thin-crystalline-silicon solar cell manufacturing process using thin epitaxial silicon lift-off processing which substantially reduces silicon usage and eliminates traditional manufacturing steps to create low-cost, high-efficiency, back-junction/back-contact monocrystalline cells. The process flow of FIG. 1A shows the fabrication of solar cells having laminated backplanes for smart cell and smart module design formed using a reusable template and epitaxial silicon deposition on a release layer of porous silicon which may utilize and integrate real-time in-situ process laser via drilling end-point detection as disclosed herein.

The process shown in FIG. 1A starts with a reusable silicon template, typically made of a p-type monocrystalline silicon wafer, onto which a thin sacrificial layer of porous silicon is formed (for example by an electrochemical etch process through a surface modification process in an HF/IPA wet chemistry in the presence of an electrical current). The starting material or reusable template may be a single crystalline silicon wafer, for example formed using crystal growth methods such as FZ, CZ, MCZ (Magnetic stabilized CZ), and may further comprise epitaxial layers grown over such silicon wafers. The semiconductor doping type may be either p or n and the wafer shape, while most commonly square shaped, may be any geometric or non-geometric shape such as quasi-square or round.

Upon formation of the sacrificial porous silicon layer, which serves both as a high-quality epitaxial seed layer as well as a subsequent separation/lift-off layer, a thin layer (for example a layer thickness in the range of a few microns up to about 70 microns, or a thickness less than approximately 50 microns) of in-situ-doped monocrystalline silicon is formed, also called epitaxial growth. The in-situ-doped monocrystalline silicon layer may be formed, for example, by atmospheric-pressure epitaxy using a chemical-vapor deposition or CVD process in ambient comprising a silicon gas such as trichlorosilane or TCS and hydrogen.

Prior to backplane lamination, the solar cell base and emitter contact metallization pattern is formed directly on the cell backside, for instance using a thin layer of screen printed or sputtered (PVD) or evaporated aluminum (or aluminum silicon alloy or Al/NiV/Sn stack) material layer. This first layer of metallization (herein referred to as M1) defines the solar cell contact metallization pattern, for example fine-pitch interdigitated back-contact (IBC) conductor fingers defining the base and emitter regions of the IBC cell. The M1 layer extracts the solar cell current and voltage and transfers the solar cell electrical power to the second level/layer of higher-conductivity solar cell metallization (herein referred to as M2) formed after M1.

After completion of a majority of solar cell processing steps, a very-low-cost backplane layer may be bonded to the thin epi layer for permanent cell support and reinforcement as well as to support the high-conductivity cell metallization of the solar cell. The backplane material may be made of a thin (for instance, a thickness in the range of approximately 50 to 250 microns and in some instances in the range of 50 to 150 microns), flexible, and electrically insulating polymeric material sheet such as an inexpensive prepreg material commonly used in printed circuit boards which meets cell process integration and reliability requirements. The mostly-processed back-contact, back-junction backplane-reinforced large-area (for instance, a solar cell area of at least 125 mm×125 mm, 156 mm×156 mm, or larger) solar cell is then separated and lifted off from the template along the mechanically-weakened sacrificial porous silicon layer (for example through a mechanical release MR process) while the template may be re-used many times to further minimize solar cell manufacturing cost. Final cell processing may then be performed on the solar cell sunny-side which is exposed after being released from the template. Sunny-side processing may include, for instance, completing frontside texturization and passivation and anti-reflection coating deposition process.

As described with reference to the flow outlined in FIG. 1A, after formation of the backplane (on or in and around M1 layer), subsequent detachment of the backplane-supported solar cell from the template along the mechanically weak sacrificial porous silicon layer, and completion of the frontside texture and passivation processes, a higher conductivity M2 layer is formed on the backplane. Via holes (in some instances up to hundreds or thousands of via holes) are drilled into the backplane (for example by laser drilling) and may have diameters in the range of approximately 50 up to 500 microns. These via holes land on pre-specified regions of M1 for subsequent electrical connections between the patterned M2 and M1 layers through conductive plugs formed in these via holes. Subsequently or in conjunction with the via holes filling and conductive plug formation, the patterned higher-conductivity metallization layer M2 is formed (for example by plasma sputtering, plating, evaporation, or a combination thereof—using an M2 material comprising aluminum, Al/NIV, Al/NiV/Sn, or copper). For an interdigitated back-contact (IBC) solar cell with fine-pitch IBC fingers on M1 (for instance, hundreds of fingers), the patterned M2 layer may be designed orthogonal to M1—in other words rectangular or tapered M2 fingers are essentially perpendicular to the M1 fingers. Because of this orthogonal transformation, the M2 layer may have far fewer IBC fingers than the M1 layer (for instance, by a factor of about 10 to 50 fewer M2 fingers). Hence, the M2 layer may be formed in a much coarser pattern with wider IBC fingers than the M1 layer. Solar cell busbars may be positioned on the M2 layer, and not on the M1 layer (in other words a busbarless M1), to eliminate electrical shading losses associated with on-cell busbars. As both the base and emitter interconnections and busbars may be positioned on the M2 layer on the solar cell backside backplane, electrical access is provided to both the base and emitter terminals of the solar cell on the backplane from the backside of the solar cell.

The backplane material formed between M1 and M2 may be a thin sheet of a polymeric material with sufficiently low coefficient of thermal expansion (CTE) to avoid causing excessive thermally induced stresses on the thin silicon layer. Moreover, the backplane material should meet process integration requirements for the backend cell fabrication processes, in particular chemical resistance during wet texturing of the cell frontside and thermal stability during the PECVD deposition of the frontside passivation and ARC layer. The electrically insulating backplane material should also meet the module-level lamination process and long-term reliability requirements. While various suitable polymeric (such as plastics, fluropolymers, prepregs, etc.) and suitable non-polymeric materials (such as glass, ceramics, etc.) may be used as the backplane material, backplane material choice depends on many considerations including, but not limited to, cost, ease of process integration, reliability, pliability, etc.

A suitable material choice for the backplane material is prepreg. Prepreg sheets are used as building blocks of printed circuit boards and may be made from combinations of resins and CTE-reducing fibers or particles. The backplane material may be an inexpensive, low-CTE (typically with CTE<10 ppm/° C., or with CTE<5 ppm/° C.), thin (for example 50 to 250 microns, and more particularly in the range of about 50 to 150 microns) prepreg sheet which is relatively chemically resistant to texturization chemicals and is thermally stable at temperatures up to at least 180° C. (or as high as at least 280° C.). The prepreg sheet may be attached to the solar cell backside while still on the template (before the cell lift off process) using a vacuum laminator. Upon applying heat and pressure, the thin prepreg sheet is permanently laminated or attached to the backside of the processed solar cell. Then, the lift-off release boundary is defined around the periphery of the solar cell (near the template edges), for example by using a pulsed laser scribing tool, and the backplane-laminated solar cell is then separated from the reusable template using a mechanical release or lift-off process. Subsequent process steps may include: (i) completion of the texture and passivation processes on the solar cell sunnyside, (ii) completion of the solar cell high conductivity metallization on the cell backside (which may comprise part of the solar cell backplane). The high-conductivity metallization M2 layer (for example comprising aluminum, copper, or silver) comprising both the emitter and base polarities is formed on the laminated solar cell backplane.

Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temperature prepregs may be fully cured by using vacuum bag pressure alone at much lower temperatures.

The viscosity of a prepreg resin affects its properties and is affected by temperature: in some examples at 20° C. a prepreg resin feels like a ‘dry’ but tacky solid. Upon heating, the resin viscosity drops dramatically, allowing it to flow around fibers, giving the prepreg the necessary flexibility to conform to mold shapes. As the prepreg is heated beyond the activation temperature, its catalysts react and the cross-linking reaction of the resin molecules accelerates. The progressive polymerization increases the viscosity of the resin until it has passed a point where it will not flow. The reaction then proceeds to full cure. Thus, prepreg material may be used to “flow” around and in gaps/voids in the M1 metallization pattern.

Further, PCBs are alternating layers of core and prepreg where core is a thin piece of dielectric with copper foil bonded to both sides (core dielectric is cured fiberglass-epoxy resin) and prepreg is uncured fiberglass-epoxy resin. Prepreg will cure and harden when heated and pressed. In other words, prepregs are rolls of uncured composite materials in which the fibers have been pre-impregnated (combined) with the resin. During production, the prepreg sandwich is heated to a precise temperature and time to slightly cure the resin and, therefore, slightly solidify through crosslinking. This is called B-Staging. Care must be taken to insure that the sandwich is not heated too much, as this will cause the prepreg to be too stiff and seem “boardy.” The solvent is removed during B-Staging so that resin is relatively dry of solvent. Typical thermoset resins and some thermoplastic resins are commonly used in prepregs. The most common resin is epoxy as the major markets for prepregs are in aerospace, sporting goods, and electrical circuit boards where excellent mechanical, chemical, and physical properties of epoxies are needed. Typically, prepregs have a thickness in the range of as little as about 1 mil (˜25 μm) up to a multiple of this amount.

Further, prepregs may be made of thermoplastics (though not as common as thermosets). Thermoplastic prepregs are often used for their toughness, solvent resistance, or some other specialized purpose. Most of the thermoplastics used are very high performance resins, such as PEEK, PEI, and PPS which would compete with 350° F. cured epoxies in aerospace applications. While new applications such as automotive body panels which depend up special properties, such as toughness, are using thermoplastics either alone or mixed with thermosets.

FIG. 1B is a representative manufacturing process flow for forming a back-contact/back-junction cell using epitaxial silicon lift-off processing may comprise the following fabrication steps: 1) start with reusable template; 2) form porous silicon on template (for example bilayer porous Si using anodic etch); 3) deposit epitaxial silicon with in-situ doping; 4) perform back-contact/back-junction cell processing while on template including M1 formation; 5) laminate backplane sheet on back-contact cell, laser scribe release border around the backplane into epitaxial silicon layer, and cell release; 7) proceed with performing back-end processes including: wet silicon etch/texture/clean, PECVD sunnyside and trench edge passivation, laser drilling of via holes in backplane, PVD deposition or evaporation of metal (—Al), or plating (Cu) for M2, and final laser ablation to complete M2 patterning.

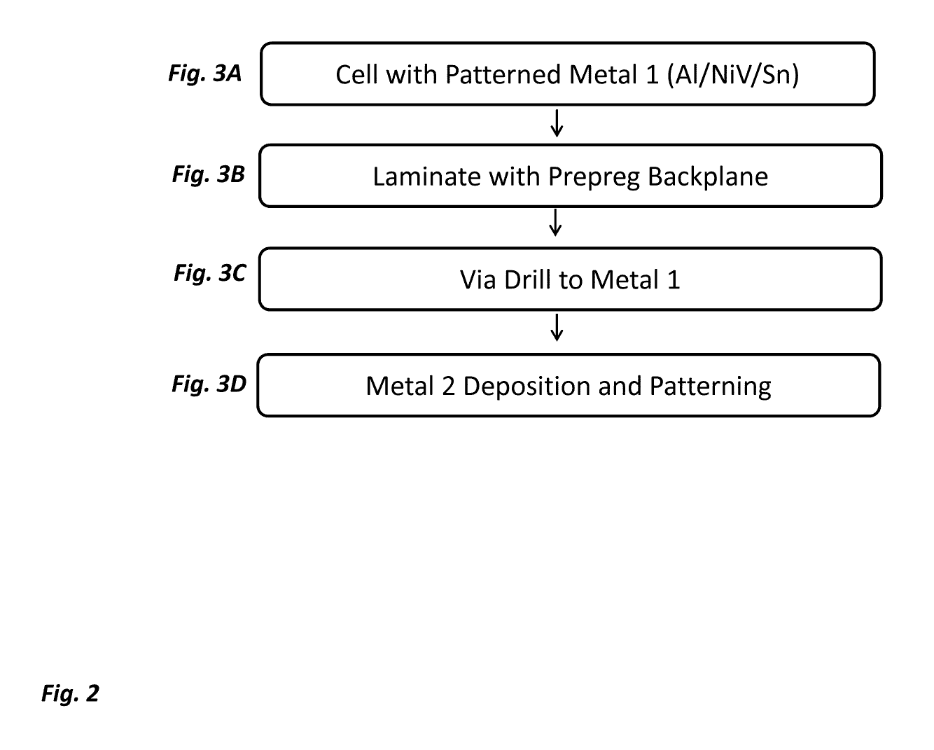

The described process flows of FIGS. 1A and 1B result in a solar cell formed on an epitaxially deposited thin silicon film with an exemplary thickness in the range of approximately 10 up to about 100 microns. FIG. 2 is a process flow highlighting metallization process steps that involve laser drilling of the backplane forming the conductive via plugs connecting metal 1 to metal 2 as described. After metal 1 is patterned (for example using PVD or evaporated Al/NiV/Sn metal deposition followed by metal laser ablation, or direct write screen printing of a metal paste such as an aluminum or aluminum-silicon alloy paste) a sheet of the backplane material (for example a prepreg sheet) is laminated on (and in some cases around) M1 and the thin silicon (for example epitaxial silicon) backplane assembly is released off the supporting template. Via holes may then be drilled (using laser drilling) through the prepreg sheet and stopping on metal 1. Metal 2 is subsequently deposited and patterned (for example using plating or a thermal spray metallization method, PVD sputtering, or an evaporated metal patterned with laser) to complete the two level metal stack.

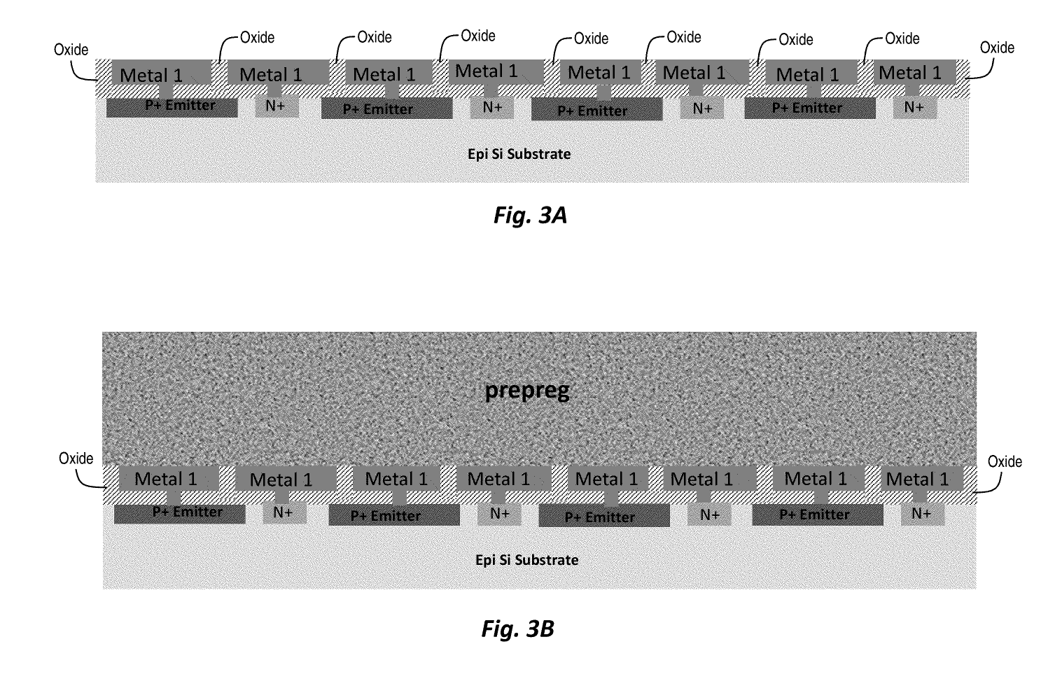

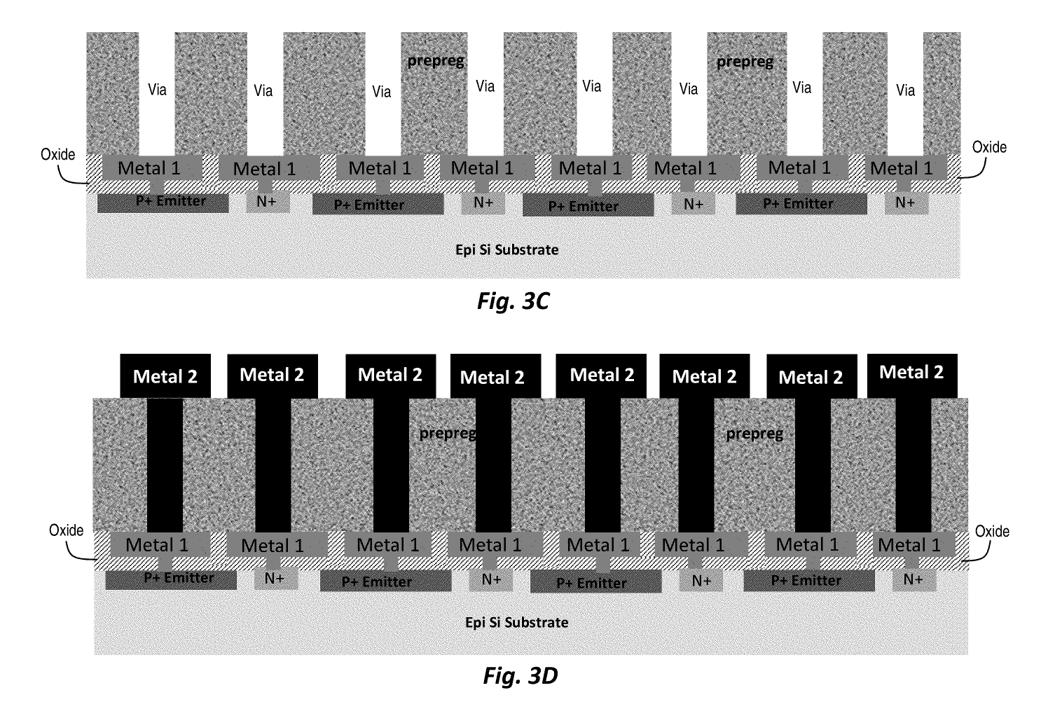

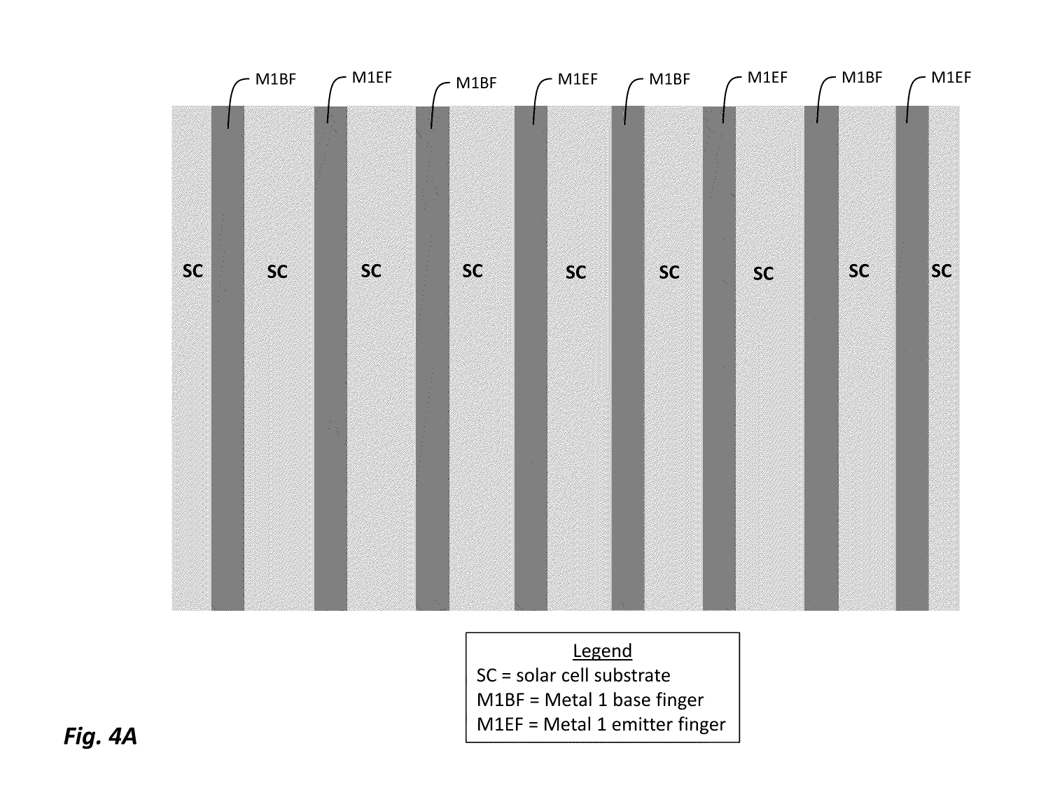

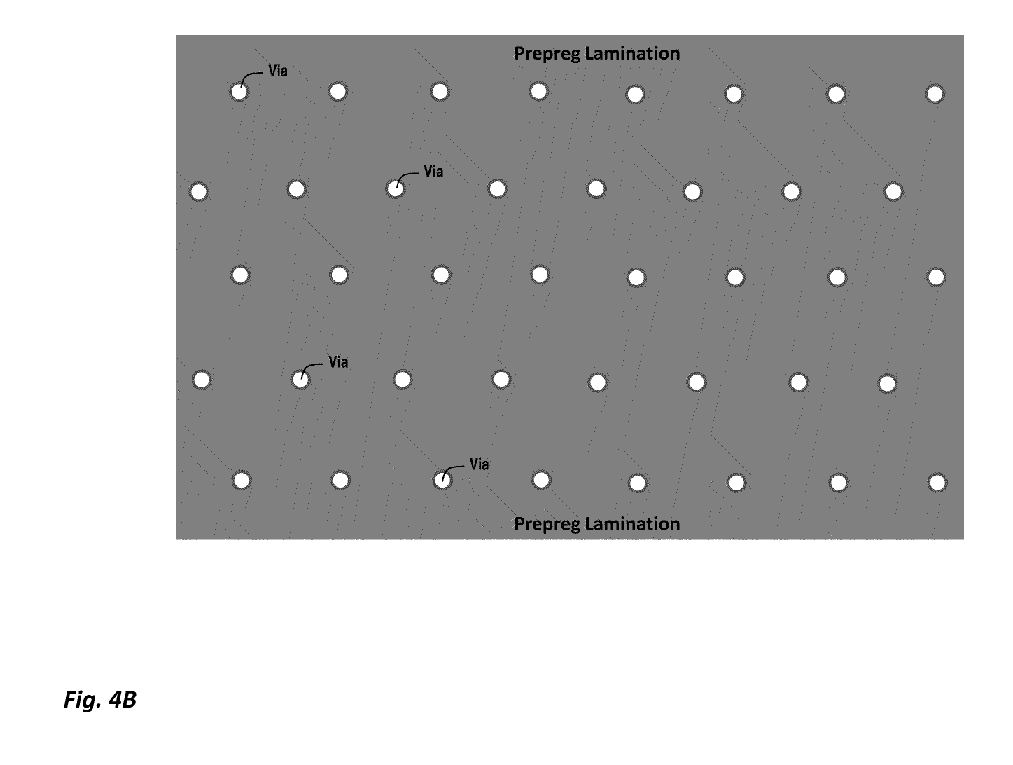

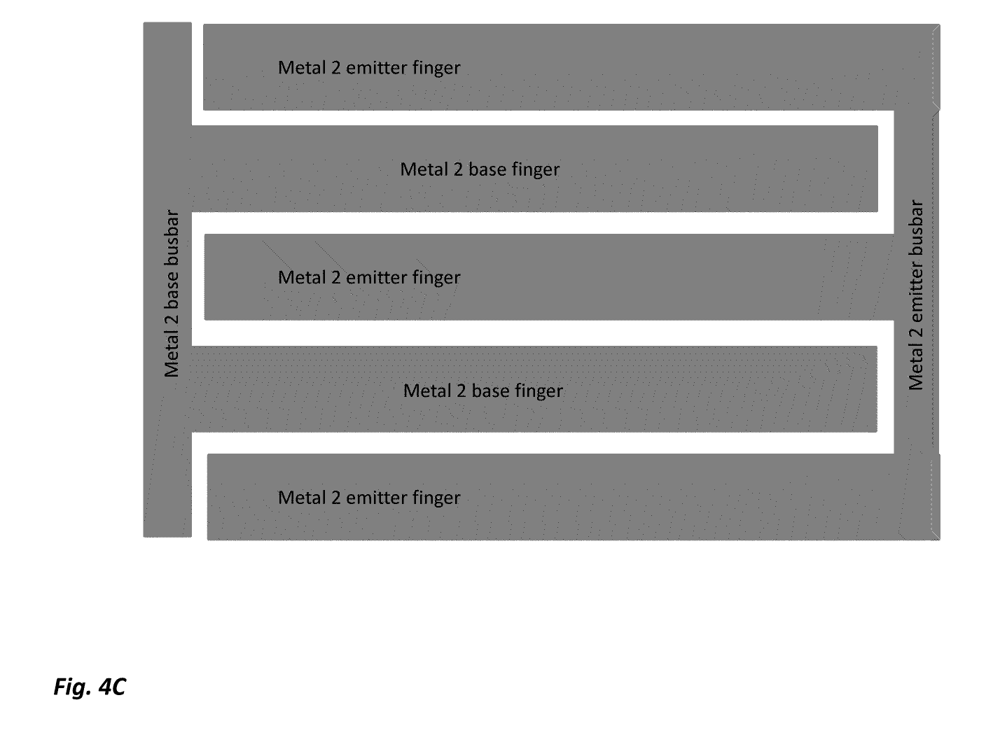

FIGS. 3A through 3D are cross-sectional diagrams showing the structure of the solar cell at each of the metallization steps described in FIG. 2. FIGS. 4A through 4C are diagrams showing backside levels of the solar cell—in other words top views of metal 1, backplane with vias, and metal 2, respectively. FIG. 3A is a cross-sectional diagram of a solar cell after on-cell metal 1 formation (for example printed aluminum paste or PVD metal). Metal 1 contacts base (N+) and emitter (P+) regions on the solar cell substrate through an oxide layer or stack (for example an undoped silicate glass USG, borosilicate glass BSG, and/or phosphorous silicate glass stack providing selective doping for forming base and emitter regions on an epitaxial silicon substrate). FIG. 4A is diagram showing a backside solar cell view of a metal 1 pattern (after metal 1 patterning or metal 1 print) corresponding to the cross-sectional view of FIG. 3A (oxide layer not shown) and comprising interdigitated metal 1 base fingers and metal 1 emitter fingers.

FIG. 3B is a cross-sectional diagram of a solar cell after backplane lamination (for example a prepreg) and thin epitaxial silicon substrate/backplane release from the template. FIG. 3C is a cross-sectional diagram of a solar cell after via holes are laser drilled through the prepreg backplane layer and exposing metal 1. FIG. 4B is diagram showing a backside solar cell view of a prepreg backplane and patterned laser drilled vias providing metal 2 layer access/contact to underlying metal 1 layer and corresponding to the cross-sectional view of FIG. 3C.

FIG. 3D is a cross-sectional diagram of a solar cell after metal 2 formation (for example by plating, thermal spray arc plasma spray, sputtering, or evaporation followed by pattterning) contacting the exposed areas of metal 1 through the vias. FIG. 4C is diagram showing a backside solar cell view of a metal 2 layer corresponding to the cross-sectional view of FIG. 3D and comprising interdigitated metal 2 emitter fingers and metal 2 base fingers and corresponding metal 2 base and emitter busbars. As shown, metal 2 is patterned orthogonally to the underlying metal 1 layer—in other words the metal 1 fingers and metal 2 fingers are two-dimensionally perpendicular. Further, the M2 pattern may comprise substantially fewer fingers as compared to M1 and may generally be formed in a coarser pattern.

The disclosed subject matter provides real-time in-situ process end pointing schemes for laser via drilling of high-efficiency solar cell backplanes particularly applicable for the fabrication of crystalline (for example mono-crystalline) semiconductor (for example silicon) solar cells (for example back-junction back-contact solar cells). The end pointing schemes disclosed herein may prevent destructive damage to the solar cells substrates by stopping the laser drilling ablation as soon as the substrate material underneath the backplane (such as a patterned metallic conductor layer M1) is exposed to the laser. In one application, the backplane layer utilizes two metallization levels where a backplane (for example a polymer sheet or a mixture thereof) separates one level of metal (for example a patterned first level metal formed directly on the cell and sandwiched between the cell backside and the backplane) from a second metal level (for example a top-level metal on top of the backplane). A laser ablation/via drilling process is used to form a plurality of patterned via holes exposing the underlying first level metal and allowing connecting of the two metal levels through the backplane. A real-time sensor-based end point process control scheme is used to effectively and consistently stop laser via drilling on the first layer of metal so that the first level metal is not detrimentally breached or punched through with the laser beam and the silicon layer under the first level metal is not damaged as a result of the laser drilling process. Thus, the fabrication embodiments disclosed herein provide for a manufacturable, low cost metallization option for high efficiency solar cells including high-efficiency back-junction, back-contact crystalline silicon solar cells.

Importantly, one or a combination of the disclosed real-time sensing and endpointing techniques may be utilized to control and manage laser via drilling by detecting the end point during ablation/drilling of the backplane sheet (for example, a suitable material such as a polymeric material)—disclosed endpointing techniques include laser induced breakdown spectroscopy (LIBS) or plasma emission technique, laser reflectance, laser interferometry, Raman spectroscopy, or photoacoustic feedback technique. Further, laser reflectance and Raman spectroscopy may be used to inspect the cells/wafers in-line after via drill to perform quality control and optimize the via drill process parameters to maintain the drill process within the specifications.

Laser via drilling processing in accordance with the disclosed subject matter may utilize a CO2 continuous wave (cw) laser, a pulsed nanosecond laser, or a picoseconds lasers. The wavelength of the laser beam may be from UV (355 nm) to IR (1064) or a CO2 laser with the wavelength in the range of 9.4 to 10.6 um. Laser choice considerations may include, for example, solar cell fabrication process throughput and cost. The backplane material separating metal 1 (M1) from metal 2 (M2) may be a low cost polymer material that meets certain solar cell process fabrication requirements, such as those outlined in FIG. 1B, and may have a thickness in the range of approximately 25 microns to 100's of microns (and in some instances having a thickness in the range of approximately 50 to 100 microns) depending on considerations such as solar cell substrate (for example epi thin film) support.

As backplane material and thickness choice (for example a thin flexible polymer sheet) may be designed to fulfill solar cell support and chemical and physical processing compatibility requirements, reliable via drilling without damaging the sensitive cell structure (for example an epi thin film) may be challenging for a number of reasons. First, in some instances the depth of via is large as compared to the other solar cell structure layers particularly M1—for example, the backplane thickness through which the via is formed may be on the order of 100 microns while the M1 thickness may be in the range of about 1 to 30 microns, dependent on other factors such as the process method used to form M1 (screen printing as compared to PVD and laser ablation). Second, M1 may be a material relatively easily ablated by the laser, such as aluminum (Al) or Al—Si metal paste consisting of micro/nano-particles, as compared to the backplane polymer. In such a case, it may be challenging to drill through a large depth and consistently stop/end drilling on M1 for every drilled via hole.

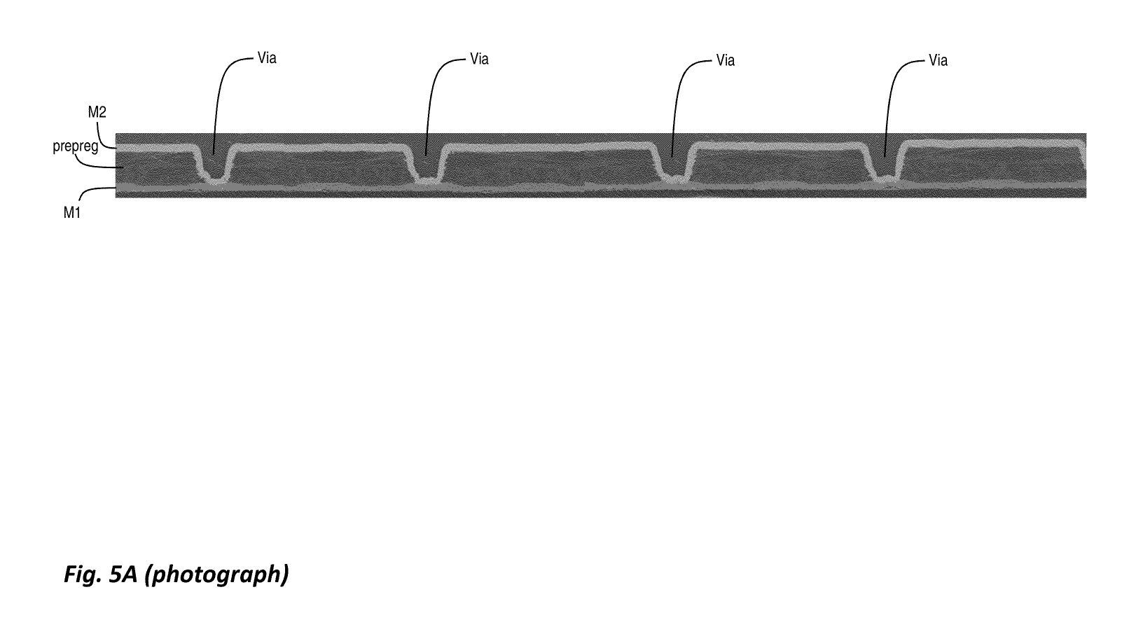

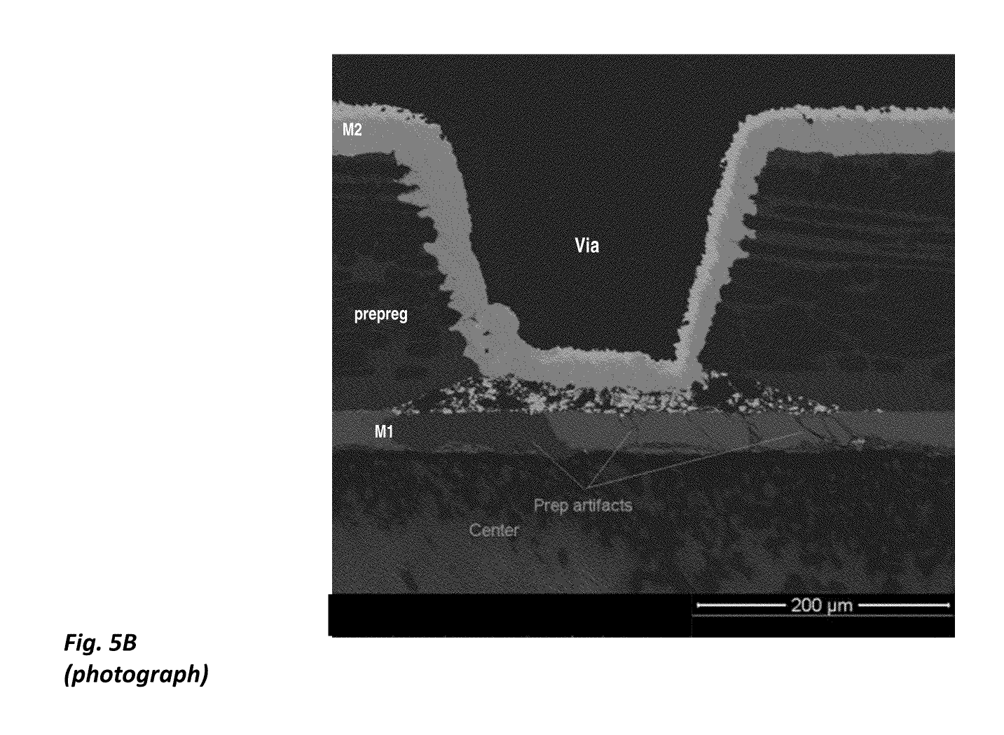

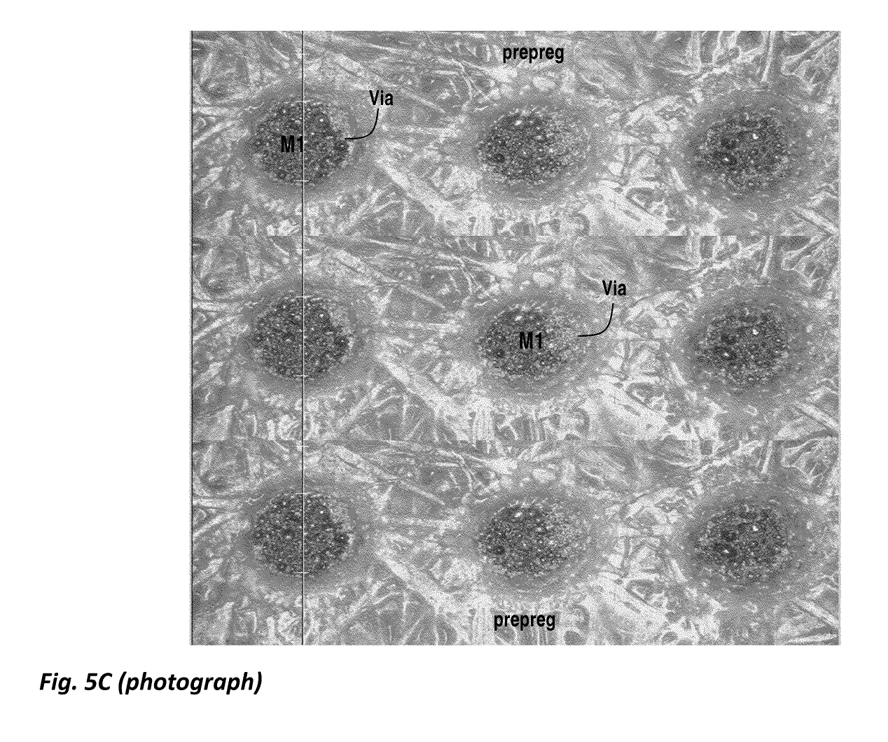

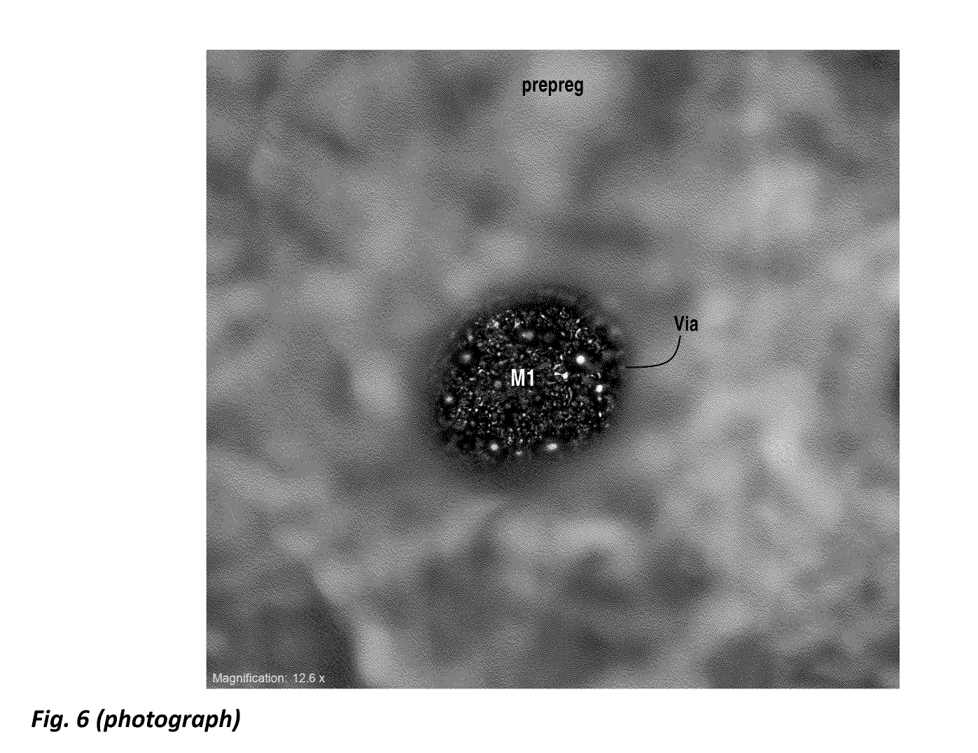

FIGS. 5A through 5C are SEM images showing vias drilled in single or double ply prepreg using a CO2 laser (wavelength 9.4 um), pulsed at 2.5 KHz to stop on an M1 layer comprising a screen printed and cured Al—Si alloy paste made up of nanoparticles. FIG. 5A is an SEM image showing a cross-section of a row of vias drilled in a pregeg sheet exposing M1 and contacting M1 and M2 (similar in structure to FIG. 3D). FIG. 5B is an SEM image showing a cross-section of an M1/Via/M2 structure in a double ply prepreg having a layer thickness of approximately 200 microns (similar in structure to FIG. 3D). FIG. 5C is an SEM image showing a top view of a via pattern formed in a single ply prepreg and exposing the underlying M1 layer (similar in structure to FIG. 4B). And FIG. 6 is a micrograph image showing a top view of a via drilled in a prepreg backplane and stopping on an underlying M1 aluminum layer.

The via quality depends on the prepreg properties such as the material type, thickness, resin content and any change in its properties as it goes through the solar cell process flow through the process flow. Also, it depends on the laser stopping properties of the M1 underneath. Because of all these reasons it is important to use real time sensor-based via drilling end point to consistently open the via and stop on M1 without punching through M1 and without damaging the cell.

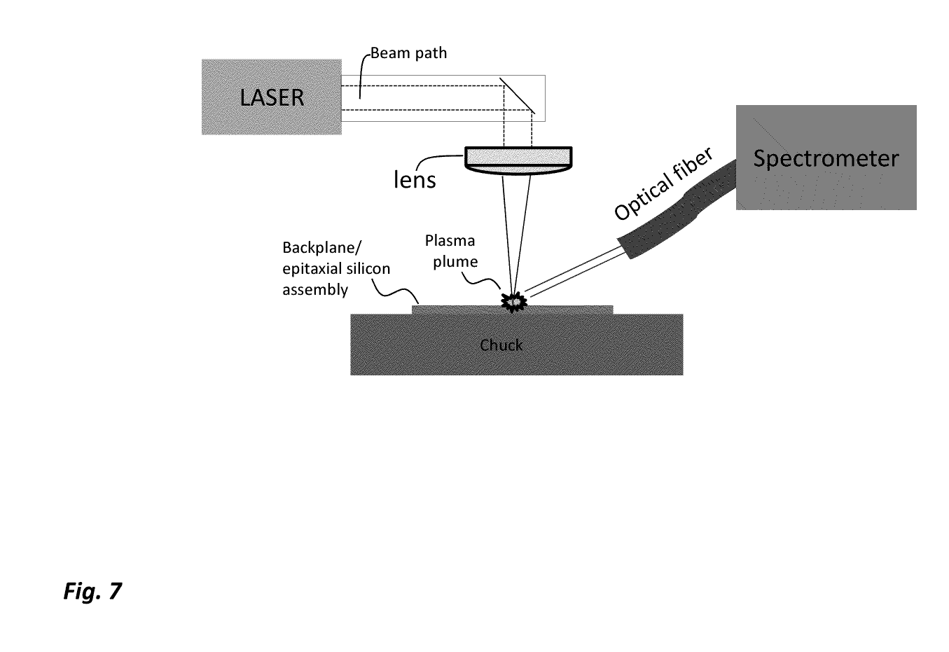

Laser Induced Breakdown Spectroscopy (LIBS) is a technique known for elemental analysis of samples. FIG. 7 is a schematic diagram showing a LIBS measurement scheme (similar to plasma endpointing). A laser beam of high enough intensity is focused on the sample (backplane side of the backplane/epitaxial silicon assembly) to generate a plasma plume as the surface of the electrostatic chuck supported sample (in this case the backplane material) is ablated. The emitted light from the laser-induced plasma plume is collected by suitable optics and delivered to the spectrometer where the spectral emission from the elements present in the plasma plume is detected.

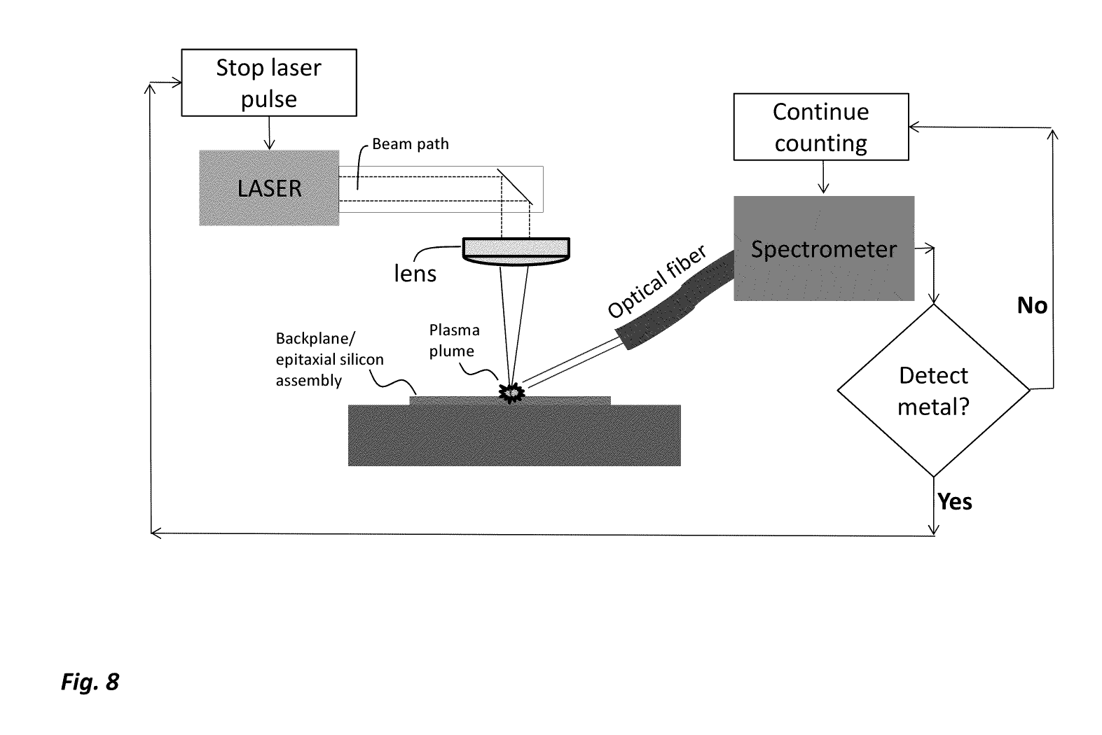

FIG. 8 is a schematic diagram showing a LIBS endpoint detection laser drilling scheme. As soon as the spectrometer detects element present in M1 (such as a signal from aluminum if M1 comprises PVD Al or cured Al paste), a command is sent to the laser controller to close the shutter (for example an AOM or EOM optical component). In some cases, the pulses produced by gating a cw CO2 laser are a few microseconds long—thus, the data acquisition and command to the laser should be done in a period less than a microsecond (for example using appropriate electronic hardware and control software).

LIBS as disclosed herein may be used to stop a long laser pulse, or alternatively, LIBS may be used to stop any further pulse from hitting the backplane during a multiple pulsed laser ablation process. This choice may depend on a number of factors including providing high quality ablation with a high throughput.

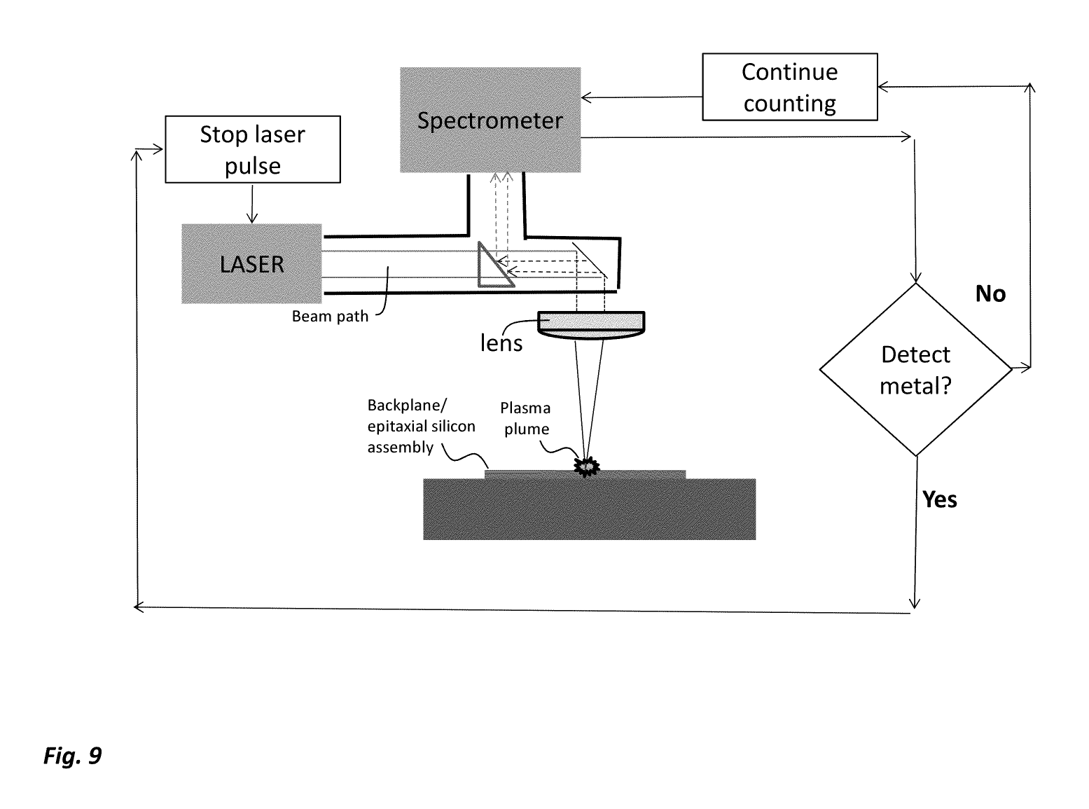

Often, in a via drilling process the laser beam is directed from one via to another by mirrors in the scanner or galvanometer. However, if the region where the spectrometer optics collecting the signal is stationary, the laser beam may move out of this region as it goes from one spot to another. Thus, synchronization of the laser beam movement with the movement of the collection area for the LIBS signal may be required. FIG. 9 is a schematic diagram showing a LIBS endpoint detection laser drilling scheme having an aligned LIBS signal collection and laser scan. As shown in FIG. 9, the reflected light from the laser beam path is collected and used for LIBS analysis. The signal collected is the light reflected through the optics in the beam path of the laser. This may be done using a beam splitter so that only the reflected light is sent to the spectrometer—thus, the light is collected from each via as the laser scans across the wafer.

It should be noted that FIG. 9 shows the concept of synchronizing the signal detection with the laser drill beam while modifications and improvements should be obvious to experts in laser optics and related fields such as spectroscopy (this also applies to the signal and drill beam synchronization described for the detection techniques described below).

In the case of very short laser times (for example less than a few microseconds) it may be difficult to stop the laser in time after the signal is detected—thus, the pulse energy may be divided into multiple pulses of lower energy. In other words, the laser beam may scan the full wafer for each pulse before coming back to the same location for the next pulse. In this case, the via where the metal signal was detected may be skipped in the next round to preventing over-ablation. Thus, providing a much longer time available for laser control.

In some cases, the intensity of the laser beam reflected from the exposed metal (Metal 1) may be greater than that reflected from the polymer backplane material (for example prepreg)—a fact which may be used to determine the laser ablation end point. For this purpose, a separate probe laser beam may be used and the probe beam reflection measured in real time to determine when each via is opened to the underlying metal (Metal 1). In practice, a low intensity laser, for example a laser having a wavelength in the range from UV (355 nm) to far IR (1064 nm), and more specifically 800 to 1064 nm, may be utilized using standard reflectometry; however, in principle, a wider range of laser wavelengths may also be used.

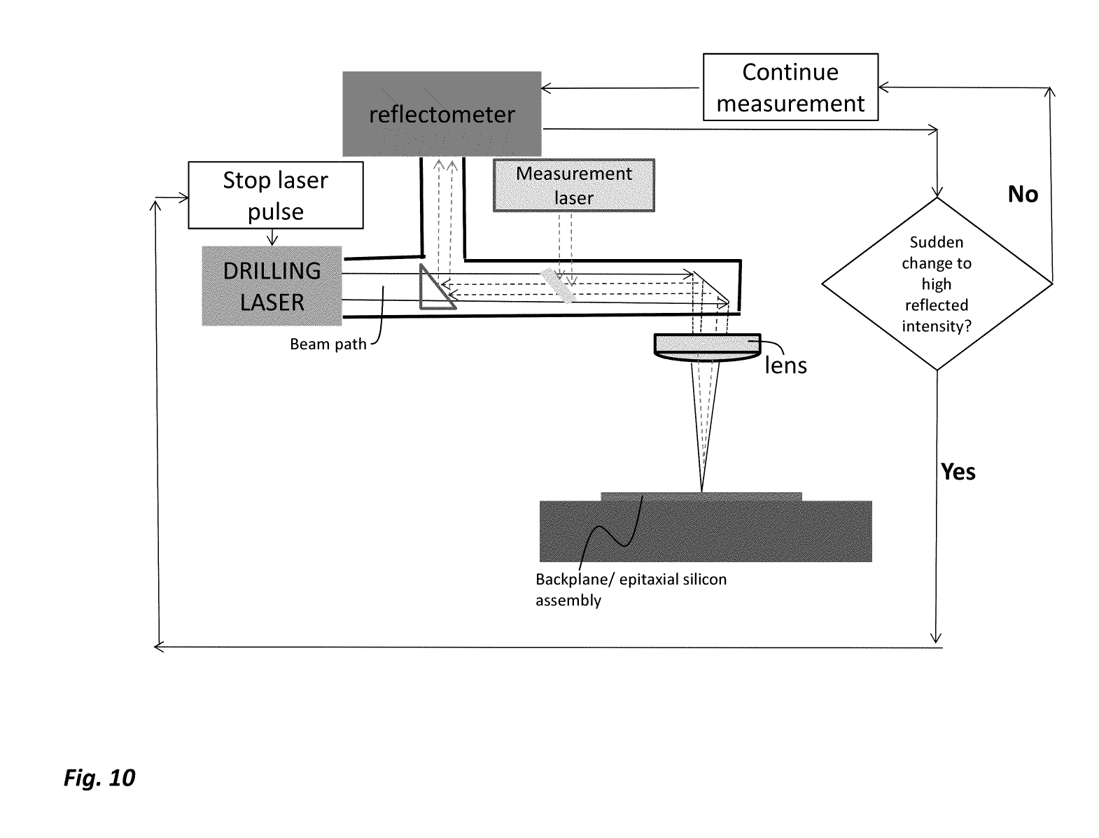

FIG. 10 is a schematic diagram showing a scheme using laser reflection for real-time endpoint detection. As shown in FIG. 10, the beam from the measurement or probe beam laser is inserted in the same path as the beam from the drilling laser. The reflected beam from the surface is diverted to a reflectometer using suitable optics. When the reflection intensity goes up because of the metal being exposed, the control circuit stops the drilling laser beam and moves to the next via hole drilling.

In yet another embodiment, using laser reflection interferometry, a secondary laser beam may be used for the purpose of real time via drilling measurement but has no effect on the prepreg/silicon film composite. An optical interference pattern may be generated by this probe/secondary laser beam if the supporting polymer sheet (for example a prepreg) is transparent or at least partially transparent to the probe/secondary beam. For the prepreg layer over metal 1 during the laser drilling process, the phase shift between the reflected beam from the top of the prepreg (or top of the remaining prepreg material in the via during the laser drilling process) and the bottom prepreg/metal interface will be Δ=4πnd, where n is the refractive index of the prepreg at the probe beam laser wavelength and d is the total thickness of the prepreg (or the remaining prepreg material in the via being drilled during the laser drilling process). These two reflected waves will interfere constructively whenever they are in phase and destructively when they are out of phase. So, an interference pattern is generated during the laser drilling process, having maxima and minima at Δ=aπ, where ‘a’ is 0, 1, 2, 3, etc. This interference pattern may be measured by an interferometer during the laser drilling process and may be calibrated for the removed and remaining thicknesses of the prepreg for process endpointing. With this calibration fed into the process control software, the drilling laser pulses may be stopped when the full thickness of prepreg is drilled.

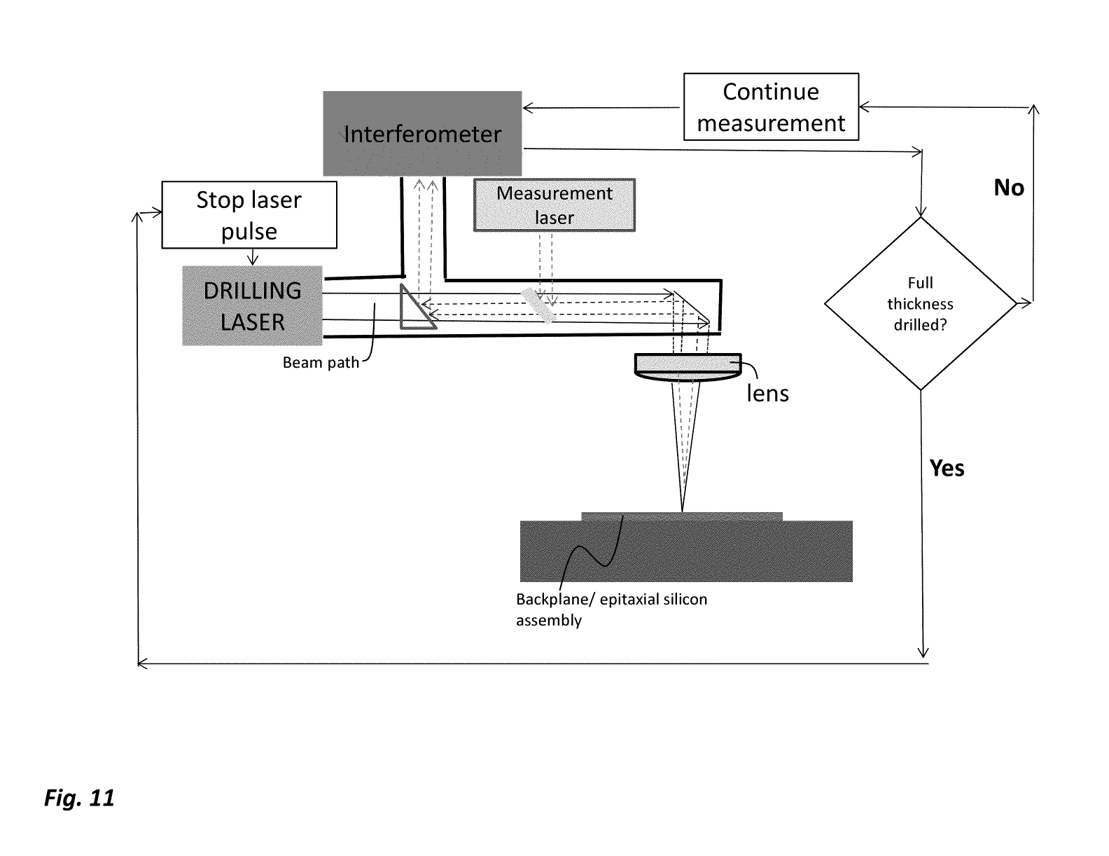

FIG. 11 is a schematic diagram showing a scheme for end pointing using laser interferometry that utilizes a secondary laser, herein referred to the measurement laser or the probe beam laser. Since the prepreg may be at least partially transparent to red and near infrared wavelengths, this probe laser may be a low power continuous wave (CW) laser with a wavelength selected in the range from red to infrared range for example in the range from 850 nm to 1065 nm (although other wavelengths, such as longer IR wavelengths, may also be used for the probe laser beam).

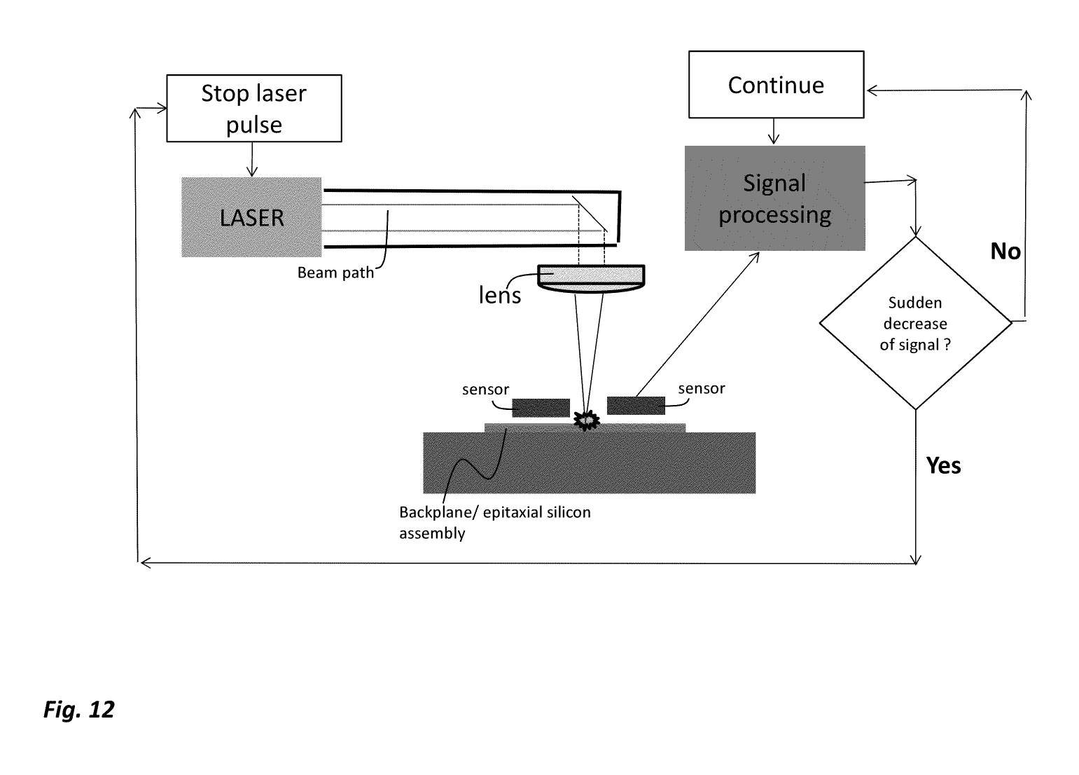

In yet another embodiment, photoacoustic signal may be used for laser endpointing wherein a photoacoustic sensor is placed close to a via to pick up the signal as the via is being drilled. FIG. 12 is a schematic diagram showing a scheme for laser end point detection using a photoacoustic signal. The photacoustic signal is produced by the drilled solid as it heats up, melts, and evaporates due to the absorption of laser energy. This heat is transferred to the surrounding gas causing a sudden localized change in gas pressure resulting in an acoustic signal which may be picked up by a suitable sensor such as a microphone or a piezoelectric sensor. The acoustic signal may then be converted to an electric signal and amplified in the signal processor used by the controller to control the drilling laser beam. For example, the acoustic signal generated by a polymer such as the prepreg is large due to the low thermal conductivity and a low dissociation temperature. On the other hand the acoustic signal generated by aluminum may be much lower because of higher reflectivity, thermal conductivity, and dissociation temperature. Thus, a sudden decrease of the signal may indicate the exposure of metal in via.

In yet another embodiment, Raman spectroscopy may be used for real time endpointing of the laser via drilling process. Raman spectroscopy is a technique based on inelastic scattering of monochromatic light, usually the light from a laser source. Upon inelastic scattering, the frequency of photons in the laser source beam changes based on interaction with the material sample. The laser source photons are absorbed by the materials being probed and then new photons with different frequencies or energies are re-emitted from the probed material. The frequency of the re-emitted photons is shifted up or down compared to the original laser wavelength due to the Raman effect. This frequency shift provides important information about the specific material elements through vibrational, rotational, and other low-frequency transitions in the molecules absorbing the source laser photons.

During the laser via drilling, Raman spectroscopy may be used to pick up signals from certain backplane materials (such as the resin and any embedded fibers or particles in the prepreg material), silicon, etc. Thus, Raman Spectroscopy may be used as an effective method for endpointing and to ensure clean via holes upon laser drilling, while preventing punching through metal-1 layer to the underlying silicon solar cell substrate. Raman spectroscopy sensing may provide real-time information to be used for either in-situ drilling process sensing and endpointing or for post-process mapping of the drilled holes to determine process controls, uniformity, and quality of the laser drilling process and identify if any vias are under-driled or over-drilled.

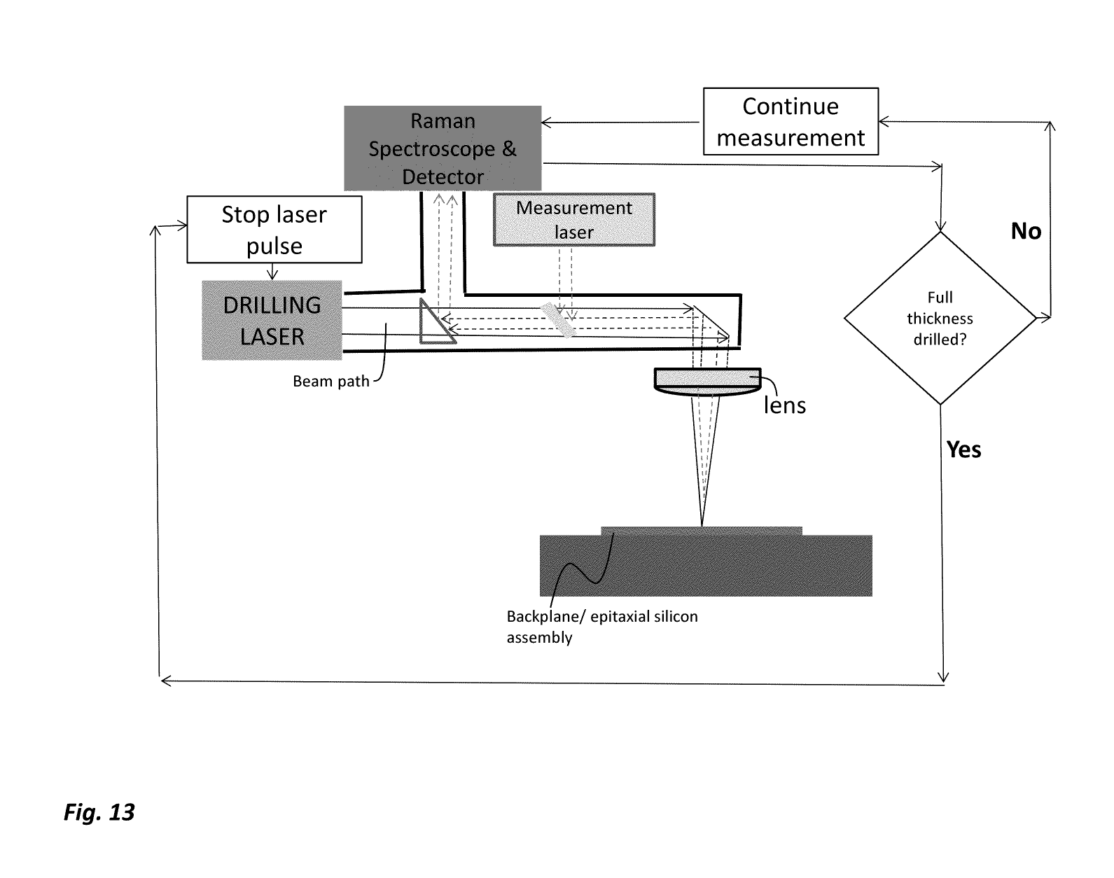

FIG. 13 is a schematic diagram showing a scheme for laser end point detection using Raman spectroscopy. For Raman spectroscopy, a low power laser (for example having a wavelength in the range of 785 nm or 514 nm) may be used to generate the Raman signal and the signal analyzed by a spectrograph. For endpointing during the via drill process, the detection laser beam is collinear with the drilling laser beam and the signal is collected as shown schematically in FIG. 13. For in-line inspection after the via drill, a spectrograph maps the wafer and the image is recorded using a detector (such as a CCD camera) and image processing is performed to evaluate the via drill quality for process control and optimization. The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for forming a back contact solar cell, comprising:
depositing a first metal layer of electrically conductive metal on a backside surface of a semiconductor solar cell substrate, said first metal layer comprising base electrodes and emitter electrodes connected to base regions and emitter regions on said semiconductor solar cell substrate;
attaching an electrically insulating backplane layer on said semiconductor solar cell substrate comprising said first metal layer;
drilling via holes in said backplane layer to said first metal layer, said via holes laser drilled through said backplane layer and said first metal layer at specified positions to expose conductive metal on said first metal layer to form base contacts and emitter contacts to said first metal layer;
detecting the via hole endpoint during said laser via drilling process to extend said via hole through said electrically insulating backplane layer to said first metal layer and prevent breaching or punching through said first level metal;
forming a second metal layer of electrically conductive metal on said backplane layer, said second metal layer contacted to said first metal layer through said via holes and providing conductive leads for electrical connections to said back-contact solar cell.

2. The method of claim 1, wherein said laser via holes are formed using a CO2 continuous wave laser.

3. The method of claim 2, wherein said laser via holes are formed using a CO2 continuous wave laser pulsed using an AOM.

4. The method of claim 1, wherein said laser via holes are formed using a laser having a wavelength in the range of UV to infrared and a pulse length in the range of approximately 1 nanosecond up to continuous wave.

5. The method of claim 1, wherein said laser via holes are formed using a laser having a wavelength in the range of approximately 9.4 to 10 microns and a pulse length in the range of approximately 1 to 100 microseconds.

6. The method of claim 1, wherein said via hole endpoint detection is performed using laser induced breakdown spectroscopy or plasma emission.

7. The method of claim 6, wherein said laser induced breakdown spectroscopy or plasma emission detects the presence of an element, said element present in said first metal layer.

8. The method of claim 6, wherein said laser induced breakdown spectroscopy or plasma emission detects the absence of an element, said element present in said electrically insulating backplane layer.

9. The method of claim 1, wherein said backplane layer is a polymeric material.

10. The method of claim 1, wherein said via hole endpoint detection is performed using laser reflectrometry.

11. The method of claim 1, wherein said via hole endpoint detection is performed using laser interferometry.

12. The method of claim 1, wherein said via hole endpoint detection is performed using the photoacoustic signal of ablated materials.

13. The method of claim 1, wherein said via hole endpoint detection is performed using the Raman spectroscopy signal of ablated materials.

14. The method of claim 1, wherein the end point detection signal is collinear with the laser ablation/drilling beam and synchronized to pick up the detection signal from the spot being drilled.

15. The method of claim 1, wherein laser reflectometry is used off-line to monitor the consistency and quality laser of drilled via holes through said electrically insulating backplane layer.

16. The method of claim 1, wherein Raman spectroscopy is used off-line to monitor the quality of drilled holes or vias in the backplane layer.
